(19) United States
(12) Patent Application Publication
(10) Pub. No.: US 2026/0353746 A1
(43) Pub. Date: Nov. 5, 2026

(54) Methods of Forming Transistor Including Asymmetric Trench Sidewall Insulator

(71) Applicant: Applied Materials, Inc., Santa Clara, CA (US)

(72) Inventors: Sipeng Gu, Lexington, MA (US); Qintao Zhang, Mt Kisco, NY (US)

(73) Assignee: Applied Materials, Inc., Santa Clara, CA (US)

(21) Appl. No.: 19/194,452

(22) Filed: Apr. 30, 2025

(51) Int. Cl. H10D 64/01; H10D 64/27; H10P 30/40; H10P 50/28

(52) U.S. Cl. CPC H10D 64/025; H10D 64/516; H10P 30/40; H10P 50/283

(57) ABSTRACT

Disclosed are approaches for forming a transistor including an asymmetric trench sidewall insulator. One approach includes providing an insulator layer along a first sidewall and a second sidewall of each trench of a plurality of trenches, wherein the plurality of trenches are formed in a base layer of a semiconductor device. The approach further incudes removing, in response to an ion treatment, the insulator layer from the first sidewall without removing the insulator layer from the second sidewall, wherein the ion treatment comprises ions delivered to the first sidewall at a non-zero angle relative to a perpendicular extending from a plane defined by an upper surface of the base layer. The approach further includes forming a second insulator layer along the first sidewall, wherein a first thickness of the insulator layer is greater than a second thickness of the second insulator layer.

### FIELD OF THE DISCLOSURE

The present disclosure relates to semiconductor structures and, more particularly, to methods of forming a transistor including an asymmetric trench sidewall insulator.

### BACKGROUND OF THE DISCLOSURE

Technological advances in semiconductor integrated circuit (IC) materials, design, processing, and manufacturing have enabled ever-shrinking IC devices, where each generation has smaller and more complex circuits than the previous generation. One specific type of IC device is an insulated gate bipolar transistor (IGBT). IGBTs combine concepts from bipolar transistors and MOSFETs to achieve an improved power device.

IGBTs with an asymmetric trench oxide have been used to increase stable, long-term operation in trench IGBTs and to reduce switching delay and gate charge without sacrificing electrical performance. One existing IGBT fabrication process for forming an asymmetric trench oxide IGBT includes starting with a homogenous thick oxide, which is covered by photoresist, and then structuring the oxide by photolithography. During the subsequent etching, this initial thick oxide is removed by etching in the channel region up to a defined position below the channel. As a last step for the formation of the gate insulator, a thermal gate oxide with a standard thickness is grown. However, this process is complex, requiring one or more mask layers. Furthermore, the time-based etch down processes leads to cross-wafer gate oxide vertical location variation, while the gate oxide region should be aligned with channel doing area to ensure high device performance.

It is with respect to these and other drawbacks of the current art that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

One approach includes providing an insulator layer along a first sidewall and a second sidewall of each trench of a plurality of trenches, wherein the plurality of trenches are formed in a base layer of a semiconductor device. The approach further incudes removing, in response to an ion treatment, the insulator layer from the first sidewall without substantially removing the insulator layer from the second sidewall, wherein the ion treatment includes ions delivered to the first sidewall at a non-zero angle relative to a perpendicular extending from a plane defined by an upper surface of the base layer. The approach further includes forming a second insulator layer along the first sidewall, wherein a first thickness of the insulator layer is greater than a second thickness of the second insulator layer.

Another approach for forming an asymmetrical trench insulator layer may include providing an insulator layer along a first sidewall and a second sidewall of each trench of a plurality of trenches, wherein the plurality of trenches are formed in a base layer of a transistor. The approach may further include removing, in response to an ion treatment, the insulator layer from an upper portion of the first sidewall without substantially removing the insulator layer from the second sidewall, wherein the ion treatment includes ions delivered to the first sidewall at a non-zero angle relative to a perpendicular extending from a plane defined by an upper surface of the base layer. The approach may further include forming a second insulator layer along the first sidewall, wherein a first thickness of the insulator layer is greater than a second thickness of the second insulator layer.

In yet another approach, forming an asymmetrical trench oxide layer may include providing a trench oxide layer along a first sidewall and a second sidewall of each trench of a plurality of trenches, wherein the plurality of trenches are formed in a base layer of a transistor. The approach may further include removing, in response to an ion treatment, the trench oxide layer from an upper portion of the first sidewall without substantially removing the trench oxide layer from the second sidewall, wherein the ion treatment includes ions delivered to the first sidewall at a non-zero angle relative to a perpendicular extending from a plane defined by an upper surface of the base layer. The approach may further include forming a second trench oxide layer along the first sidewall, wherein a first thickness of the trench oxide layer is greater than a second thickness of the second trench oxide layer.

### BRIEF DESCRIPTION OF THE DRAWINGS

The accompanying drawings illustrate exemplary approaches of the disclosure, including the practical application of the principles thereof, as follows:

FIG. 1 illustrates a side cross-sectional view of a device at one stage of processing, the device including an insulator layer along trench sidewalls, according to embodiments of the present disclosure;

FIG. 2 illustrates a side cross-sectional view of the device following an angled etch process, according to embodiments of the present disclosure;

FIG. 3 illustrates a side cross-sectional view of the device following an oxide regrowth process, according to embodiments of the present disclosure;

FIG. 4 illustrates a side cross-sectional view of the device following further device processing, according to embodiments of the present disclosure;

FIG. 5 illustrates a side cross-sectional view of a device during an ion treatment, according to embodiments of the present disclosure;

FIG. 6 illustrates a side cross-sectional view of the device following an etch process, according to embodiments of the present disclosure;

FIG. 7 illustrates a side cross-sectional view of following an oxide regrowth process, according to embodiments of the present disclosure;

FIG. 8 illustrates a diagram of a cluster tool according to embodiments of the present disclosure.

FIG. 9 illustrates a diagram of a processing apparatus according to embodiments of the present disclosure.

FIG. 10 illustrates a diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, disclosed herein are simplified approaches for forming an asymmetric gate oxide of a transistor (e.g., IGBT) using a directional ion treatment process, such as an etch or an implant delivered at a non-zero angle relative to IGBT. The directional ion treatment results in a portion of a gate oxide layer being removed from a first trench sidewall without removing, or partially removing, the gate oxide layer from a second trench sidewall. A subsequent oxidation process forms a second, relatively thinner trench oxide layer along the first trench sidewall. Processing of the transistor may then continue, e.g., by forming a gate material within the trenches following formation of the second trench oxide layer.

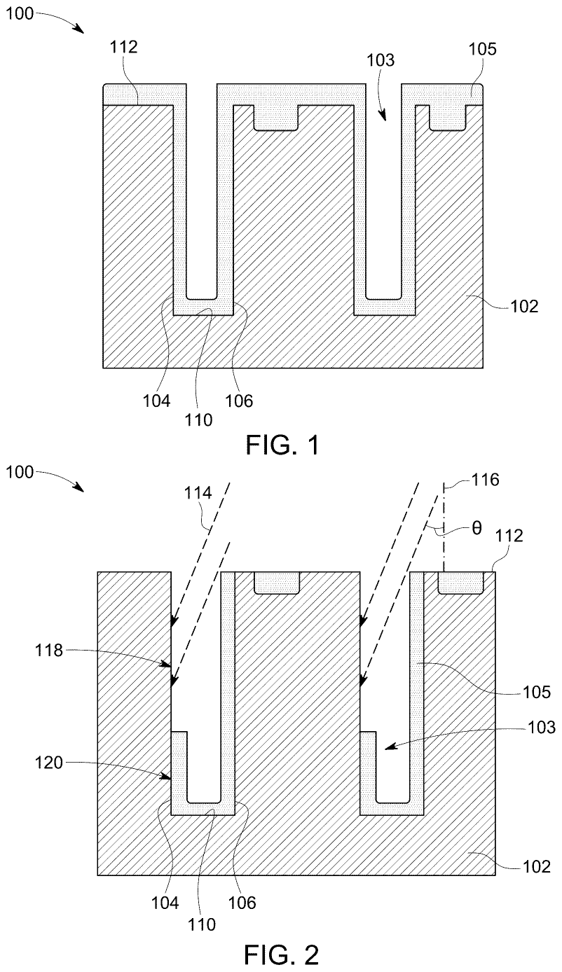

FIG. 1 is a side cross-sectional view of a portion of a semiconductor device (hereinafter “device”) 100, such as an IGBT, at one stage of processing, according to embodiments of the present disclosure. As shown, the device 100 may include a base layer or substrate 102, which may be an N-doped base formed over a fieldstop layer (not shown). A plurality of trenches 103 may be formed in the substrate 102, and an insulator layer 105 may be formed over the device 100, including within each of the trenches 103. More specifically, the insulator layer 105 may be an oxide or nitride, which is conformally formed along a first sidewall 104, a second sidewall 106, and a base 110 of each trench 103. The insulator layer 105 may be further formed along an upper surface 112 of the substrate 102. Although non-limiting, the material of the insulator layer 105 may be formed by chemical vapor deposition (CVD), low-pressure chemical vapor deposition (LPCVD), plasma enhanced chemical vapor deposition (PECVD), atomic layer deposition (ALD), or a combination thereof. Other insulative materials formed by any acceptable process may be used.

As shown in FIG. 2, an ion treatment may be performed in which ions 114 are directed to the device 100 at a non-zero angle (θ) relative to a perpendicular 116 extending from the upper surface 112 of the substrate. In the embodiment shown, the ions 114 may be delivered as part of a removal process, e.g., angled reactive ion beam etch (RIE), to remove a select section of the insulator layer 105 from an upper portion 118 of the first sidewall 104. As shown, the insulator layer 105 remains along a lower portion 120 of the first sidewall 104 and along the second sidewall 106. Due to the angle of the ion delivery, the RIE may also be prevented from removing the insulator layer 105 from the base 110 of the trenches 103. As further shown, the RIE process may remove the insulator layer 105 from the upper surface 112 of the substrate 102. During the ion treatment, a plasma may generate various species to perform the RIE, depending upon the exact composition of species provided to a plasma chamber (not shown). The species provided by the source may be selected according to the material to be etched, such as known reactive ion etching species for etching one or more oxide materials of the insulator layer 105. To achieve the desired non-zero angle relative to the perpendicular 116, a wafer support (not shown) supporting the device 100 and/or a tool (not shown) providing the ions 114 may be oriented or angled. Embodiments herein are not limited in this context.

In other embodiments, the insulator layer 105 may be removed using a gas cluster ion beam (GCIB) infusion process. As used herein, gas clusters are nano-sized aggregates of materials that are gaseous under conditions of standard temperature and pressure. Such gas clusters may consist of aggregates including a few to several thousand molecules, or more, that are loosely bound together. The gas clusters can be ionized by electron bombardment, which permits the gas clusters to be formed into directed beams of controllable energy. Such ionized clusters each may carry positive charges given by the product of the magnitude of the electronic charge and an integer greater than or equal to one that represents the charge state of the cluster ion.

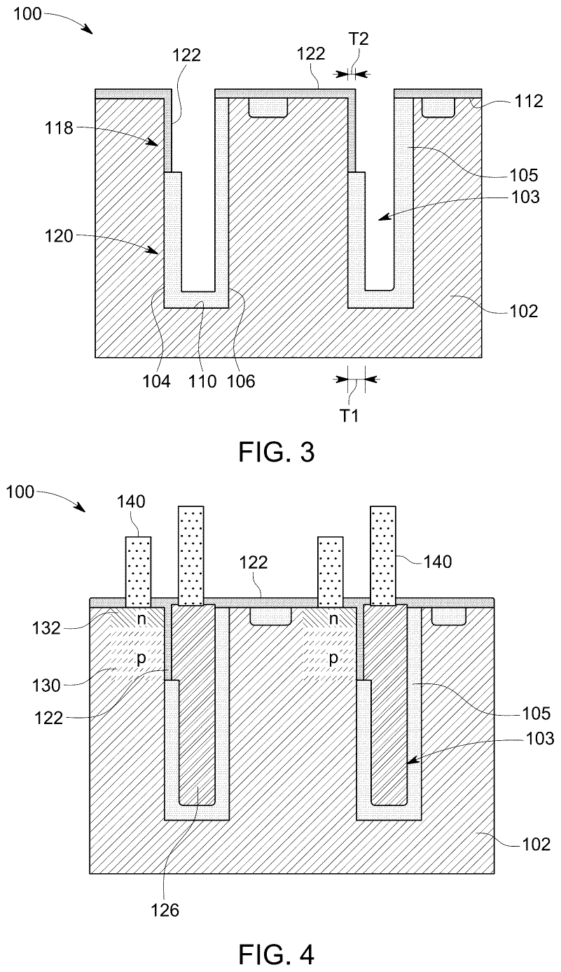

As shown in FIG. 3, after the insulator layer 105 is removed from the upper portion 118 of the first sidewall 104, a second insulator layer 122 may be formed over the device 100. More specifically, the second insulator layer 122 may be formed along the upper portion 118 of the first sidewall 104. The second insulator layer 122 may also be formed along the upper surface 112 of the substrate 102. Although non-limiting, the second insulator layer 122 may be a thin oxide layer formed by CVD/LPCVD, PECVD, furnace CVD, ALD, or other suitable oxide growth process. In various embodiments, the second insulator layer 122 may be the same or different material as the insulator layer 105. As shown, a first thickness (T1) of the insulator layer 105, in a lateral/horizontal direction, may be greater than a second thickness (T2) of the second insulator layer 122, thus creating an asymmetric trench gate oxide.

As shown in FIG. 4, following formation of the second insulator layer 122, processing of the device 100 may continue, e.g., by forming a gate material 126 within the trenches 103. The gate material 126 may be thicker along an upper section of trenches 103 than along a lower section of the trenches 103 because of the different thicknesses of the insulator layer 105 and the second insulator layer 122. Processing may further include forming a p-body 130 and an n+ contact region 132 adjacent the second insulator layer 122, and a plurality of metal contacts 140 of the gate and emitter. Although both are demonstrated, in some embodiments, the metal 140 of the gate and emitter may not be visible in the same cross section surface.

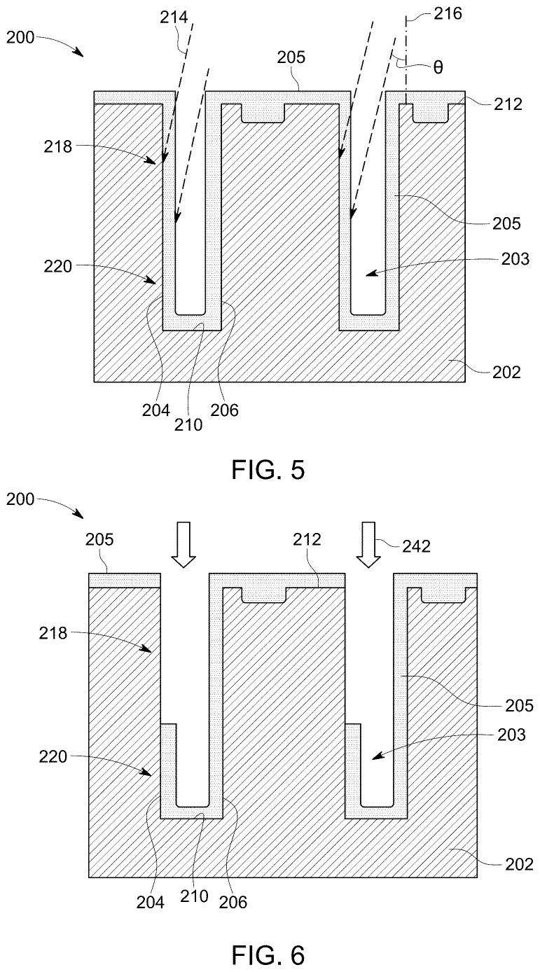

Turning to FIG. 5, another approach for forming a device 200 is shown. The device 200 may share many of the same features as the device 100 described herein. As such, only certain aspects of the device 200 will hereinafter be described for the sake of brevity. As shown, the device 200 may include a base layer or substrate 202, which may be an N-doped base formed over a fieldstop layer (not shown). A plurality of trenches 203 may be formed in the substrate 202, and an insulator layer 205 may be formed over the device 200, including within each of the trenches 203. The insulator layer 205 may be an oxide or nitride, which is conformally formed along a first sidewall 206, a second sidewall 208, and a base 210 of each trench 203. The insulator layer 205 may also be present along an upper surface 212 of the substrate 202.

As further shown, an ion treatment may be performed in which ions 214 are directed to the device 200 at a non-zero angle (θ) relative to a perpendicular 216 extending from the upper surface 212 of the substrate. In the embodiment shown, the ions 214 may be delivered as part of a precision materials engineering (PME) process to modify an etch rate of certain portions of the insulator 205. That is, the ions 214 may impact the insulator layer 205 along an upper portion 218 of the first sidewall 204. However, the ions 214 generally do not impact the insulator layer 205 along a lower portion 220 of the first sidewall 204 or along the second sidewall 206. Due to the angle of the ion delivery, the ions 214 may also be prevented from impacting the insulator layer 205 along the base 210 of the trenches 203. Although non-limiting, the ions 214 may include oxygen (O), fluorine (F), silicon (Si), argon (Ar), krypton (Kr) or others to increase the etch rate of the insulator layer 205, which may be silicon dioxide (SiO2). This etch rate modifying species increases the difference in etch rates of the insulator layer 205 along the upper portion 218 of the first sidewall 204 relative to the lower portion 220 of the first sidewall 204. As a result, when the device 200 is etched, as demonstrated in FIG. 6, only the insulator layer 205 along the upper portion 218 of the first sidewall 204 is removed selective to the first sidewall 204. Other portions of the insulator layer 205 may also be reduced, but not eliminated. More specifically, the insulator layer 205 along the lower portion 220 of the first sidewall 204, and the insulator layer 205 along the second sidewall 208, may be thinned by the etch process.

In some embodiments, etch process 242 of FIG. 6 may be a wet etch process (e.g., hydrofluoric acid). In alternative embodiments, the etch process 242 may include phosphoric acid (H₃PO₄), one or more hydroxides (e.g., sodium hydroxide (NaOH), potassium hydroxide (KOH), lithium hydroxide (LiOH), ammonium hydroxide (NH₄OH)), or salts thereof. A dilute hydrofluoric acid (DHF) solution having a concentration from about 50:1 to about 1,000:1 (in water) can be used in some embodiments. However, the etching chemistry may vary in alternative embodiments, and can be selected based on the composition of the insulator layer 205 to be removed.

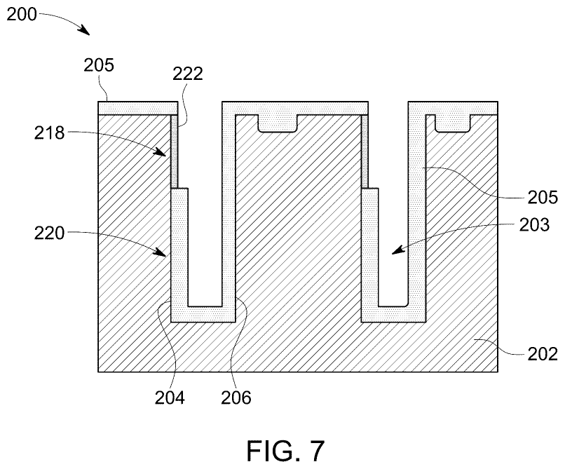

As shown in FIG. 7, after the insulator layer 205 is etched from the upper portion 218 of the first sidewall 204, a second insulator layer 222 may be formed over the device 200. More specifically, the second insulator layer 222 may be formed along the upper portion 218 of the first sidewall 204 left exposed by the etch process 242. Although non-limiting, the second insulator layer 222 may be a thin oxide layer formed by CVD/LPCVD, PECVD, furnace CVD, ALD, or other suitable oxide growth process. As shown, a first thickness of the insulator layer 205, in a lateral/horizontal direction, may be greater than a second thickness of the second insulator layer 222, thus creating an asymmetric trench gate oxide.

Similar to the process shown in FIG. 4, following formation of the second insulator layer 222, processing of the device 200 may continue, e.g., by forming a gate material within the trenches 203, forming a p-body and an n+ contact region adjacent the second insulator layer 222, and by forming a plurality of metal contacts.

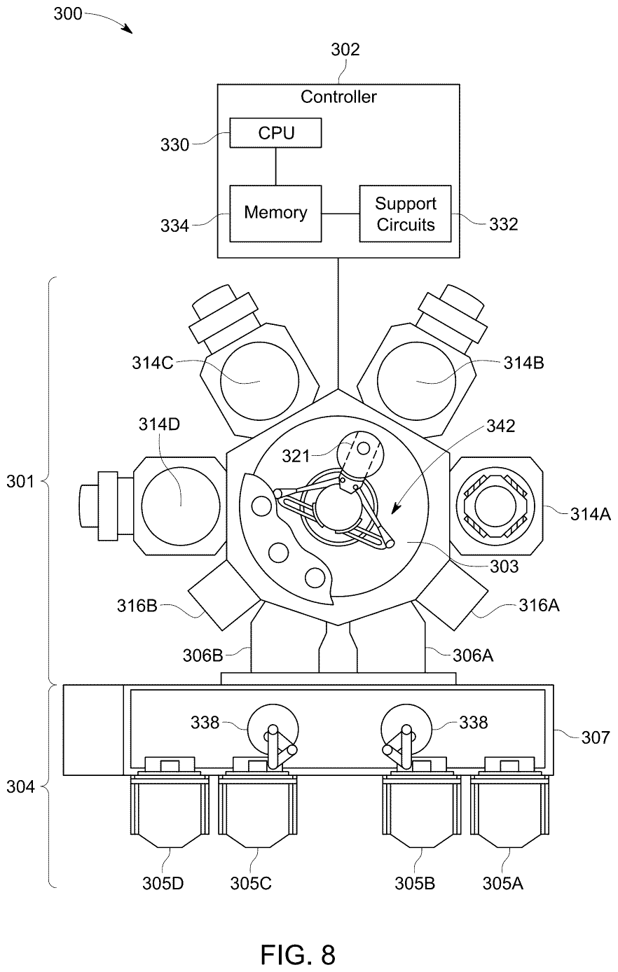

The approaches described above may be performed in a tool or system, such as an integrated tool or a cluster tool 300, as shown in FIG. 8. The tool 300 may include suitable process chambers configured for one or more of epitaxial growth, ion delivery, dopant delivery, and etching, etc.

In some embodiments, the tool 300 facilitates operation of the methods described herein with limited or no vacuum breaks between processes. Reduced vacuum breaks may limit or prevent contamination and may further enhance throughput by reducing the amount of time between processes and reducing or eliminating certain processes such as pre-clean operations or other operations that would otherwise be required where the process to be performed sequentially in standalone process chambers.

The tool 300 may include a processing platform 301, a factory interface 304, and a system controller 302. The processing platform 301 may include multiple process chambers 314A-314N operatively coupled to a transfer chamber 303. The factory interface 304 is operatively coupled to the transfer chamber 303 by one or more load lock chambers, such as 306A and 306B.

In some embodiments, the factory interface 304 includes at least one docking station 307 and at least one factory interface robot 338 to facilitate the transfer of one or more semiconductor substrates 321 (e.g., wafers). The docking station 307 is configured to accept one or more front opening unified pods (FOUP) 305A, 305B, 305C, and 305D. The factory interface robot 338 is configured to transfer the substrates 321 from the factory interface 304 to the processing platform 301 through load lock chambers 306A and 306B. Each of the load lock chambers 306A and 306B have a first port coupled to the factory interface 304 and a second port coupled to the transfer chamber 303. The load lock chamber 306A and 306B are coupled to a pressure control system (not shown), which pumps down and vents the load lock chambers 306A and 306B to facilitate passing the substrates 321 between the vacuum environment of the transfer chamber 303 and the substantially ambient (e.g., atmospheric) environment of the factory interface 304. The transfer chamber 303 may have a vacuum robot 342 disposed within the transfer chamber 303, wherein the vacuum robot 342 is capable of transferring substrates 321 between the load lock chamber 306A and 306B and the process chambers 314A-314N.

Each of the process chambers 314A-314N, can be outfitted to perform a number of substrate processing operations described herein including, but not limited to, depositing, treating, growing, thermally processing (e.g., annealing), curing, implanting, and/or etching the substrate and/or on or more material layers on the substrate or wafer. In one non-limiting configuration, the process chambers 314A-314N may include at least a material deposition/formation chamber 314A, an ion implant and/or plasma implant chamber 314B, a material removal chamber 314C, and a thermal treatment (e.g., anneal) chamber 314D.

In some embodiments, one or more optional service chambers (shown as 316A and 316B) may be coupled to the transfer chamber 303. The service chambers 316A and 316B may be configured to perform other substrate processes, such as degassing, bonding, chemical mechanical polishing (CMP), wafer cleaving, etching, plasma dicing, orientation, substrate metrology, cool down and the like.

The system controller 302 controls the operation of the tool 300 using direct control of the process chambers 314A-314D or, alternatively, by controlling the computers (or controllers) associated with the process chambers 314A-314D and the tool 300. In operation, the system controller 302 enables data collection and feedback from the respective chambers and systems to optimize performance of the tool 300. The system controller 302 generally includes a central processing unit (CPU) 330, a memory 334, and a support circuit 332. The CPU 330 may be any form of a general-purpose computer processor that can be used in an industrial setting. The support circuit 332 is conventionally coupled to the CPU 330 and may comprise a cache, clock circuits, input/output subsystems, power supplies, and the like. Software routines, such as processing methods as described above may be stored in the memory 334 (e.g., non-transitory computer readable storage medium) and, when executed by the CPU 330, transform the CPU 330 into a specific purpose computer (system controller 302). The software routines may also be stored and/or executed by a second controller (not shown) that is located remotely from the tool 300.

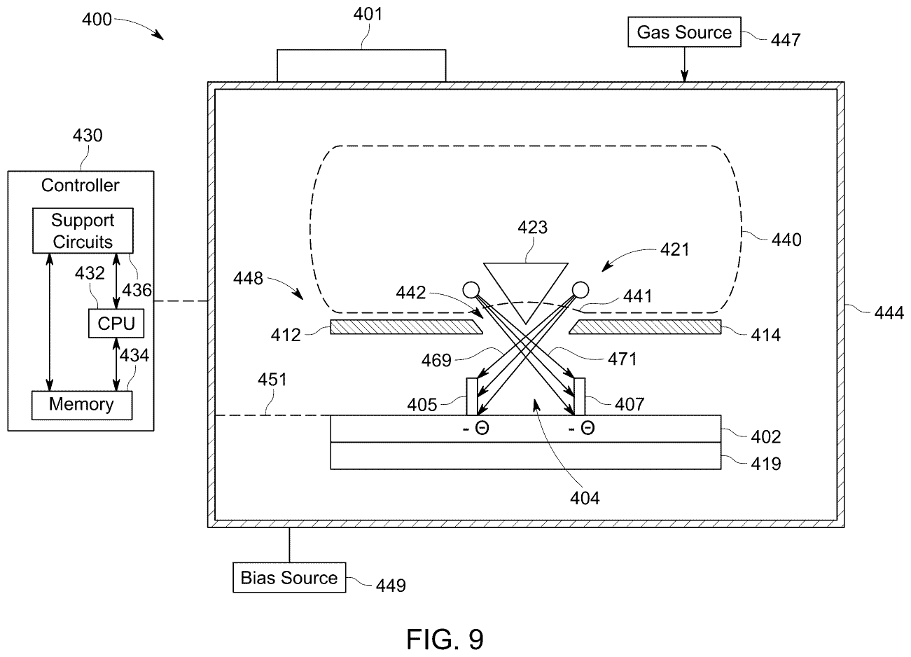

FIG. 9 illustrates a schematic diagram of a processing apparatus 400 useful to perform processes described herein. The processing apparatus 400 is representative of a uni-directional or bi-directional plasma implantation apparatus, and may be located within the ion implant and/or plasma implant chamber 314B of the tool 300 shown in FIG. 8. In some embodiments, the processing apparatus 400 is an ion assisted directional plasma treatment (PME) system operable to selectively treat and then remove portions of the trench oxide, as described herein. For example, the processing apparatus 400 may be used to perform the ion treatment shown in FIG. 5 in which ions are delivered as part of a PME process to modify an etch rate of certain portions of the insulator layer. In other embodiments, the ion treatment may be an ion implantation process performed by beamline or plasma implantation tools, wherein the beamline tool may be part of tool 300.

As shown, the processing apparatus 400 may include a process chamber 444, a platen 419, a source 401, and a modifying element 448. The platen 419 may be positioned in the processing chamber 444 for supporting the substrate 402. The platen 419 may be coupled to an actuator (not shown) which may cause the platen 419 to move in a scanning motion. The scanning motion may be a back-and-forth movement within a single plane which may be substantially parallel to the modifying element 448. The source 401 is configured to generate the plasma 440 in the process chamber 444. The modifying element 448 includes a pair of insulators 412, 414 which may define a gap therebetween having a horizontal spacing. The insulators 412, 414 may include an insulating material, a semi-conducting material, or a conductive material. The modifying element 448 also includes a directional element 423 disposed in a position relative to the insulators 412, 414 to define a directional pathway for ions 421 delivered toward the substrate 402. In some examples, the platen 419 may be heated or cooled to a desired temperature.

In operation, a gas source 447 may supply an ionizable gas to the process chamber 444. The source 401 may generate plasma 440 by exciting and ionizing the gas provided to the process chamber 444. The ions 421 are attracted from the plasma 440 across a plasma sheath 442. For example, a bias source 449 is configured to bias the substrate 402 to attract the ions 421 from the plasma 440 across the plasma sheath 442. The bias source 449 may be a DC power supply to provide a DC voltage bias signal or an RF power supply to provide an RF bias signal.

The modifying element 448 modifies the electric field within the plasma sheath 442 to control a shape of the boundary 441 between the plasma 440 and the plasma sheath 442. The modifying element 448 includes the insulators 412, 414 and directional element 423. The insulators 412, 414 and directional element 423 may be fabricated from materials such as quartz, alumina, boron nitride, glass, silicon nitride, silicon, silicon carbide, doped silicon, graphite, and other suitable materials. A boundary 441 between the plasma 440 and the plasma sheath 442 may be dependent upon the placement of the directional element 423 relative to the insulators 412, 414 as the directional element 423 may alter the electric field within the plasma sheath 442.

Ions following a trajectory path 471 may strike the substrate 402 at about an angle of +θ normal to the plane 451. Ions following trajectory path 469 may strike the substrate 402 at an angle of about −θ normal to the plane 451. Although non-limiting, the range of incident angles normal to the plane 451 may be between about +1° and about +89° and between about −1° and about −89°, excluding 0°. For example, a first range of incident angle normal to the plane 451 may be between about +30° and about +80° and a second range of incident angle may be between about −30° and about −80°. In one embodiment, the first range of incident angle relative to the plane 451 may be between about −40° and about −70° and the second range of incident angle relative to the plane 451 may be between about +40° and about +70°. In addition, some ion trajectories, such as paths 469 and 471, may cross one another.

Depending on a number of factors including, but not limited to, the positioning of the directional element 423, the horizontal spacing between the insulators 412, 414, the vertical spacing (Z) of the insulators 412, 414 above the plane 451, the dielectric constant of the directional element 423 and the insulators 412, 414 and other plasma processing parameters, the range of incident angle (θ) as described above, is between about +89° and about −89°, exclusive of 0°. Embodiments herein are not limited in this context, however.

Furthermore, the range of incident angle may be selected based upon an aspect ratio of one or more trenches on the substrate 402. For example, sidewalls 405, 407 of a trench 404 having one or more insulator layers formed thereon, having an exaggerated size for clarity of illustration, may be more accurately treated by the ions 421 than with conventional plasma processing apparatuses and procedures. For example, by utilizing a bimodal ion distribution, only desired areas of the features may be modified as a result of shadowing effects and the ion trajectory. The aspect ratio, which may be defined as the relationship between a pitch between the sidewalls 405, 407 and a height of the sidewalls 405, 407 extending from the substrate 402, may determine the trajectory at which the ions 421 are directed toward the trench 404. In one embodiment, the trajectory of the ions 421 and the incident angle relative to the plane 451 may be selected to avoid contact with material along a lower portion of sidewall 405. It is also contemplated that different angle and ion trajectories may be selected for different orientations of features disposed on the substrate 402.

The above-described processing apparatus 400 can be controlled by a processor-based system controller such as the controller 430, the support circuits 436, the CPU 432, and memory 434. For example, the controller 430 may be configured to control flow of various precursor and process gases from gas sources and control processing parameters associated with directional ion implantation processes.

As previously described, the plasma processing apparatus 400 is only one example of an apparatus that may be used. Other apparatuses, such as those capable of generating spot beams, pattern beams, electron beams (e.g., pulsed or continuous), raster scanning, and variable scanning, may be used. Any other method of directionally implanting ions may also be used. According to certain aspects, one or more energetic particle beams may include a cylindrical shaped beam, a plurality of adjacent or overlapping cylindrical beams, or a ribbon shaped beam (e.g., a continuous rectangular shaped beam). The one or more energetic particle beams can be moved relative to the substrate 402 during processing and/or the substrate 402 can be moved relative to the energetic particle beam during processing.

Furthermore, different processing characteristics may be used, such as beam energy, beam angle, beam angle relative to the transfer direction of the substrate 402, and beam composition (e.g., gas ions), among other processing characteristics, may be utilized to implant one or more features or layers formed on the substrate 402. For example, in some embodiments, the plasma processing apparatus 400 may be a GCIB or gas cluster beam (GCB) tool operable to selectively treat and portions of the trench oxide, as described herein. GCIBs may also be used for etching, cleaning, smoothing, and forming thin films.

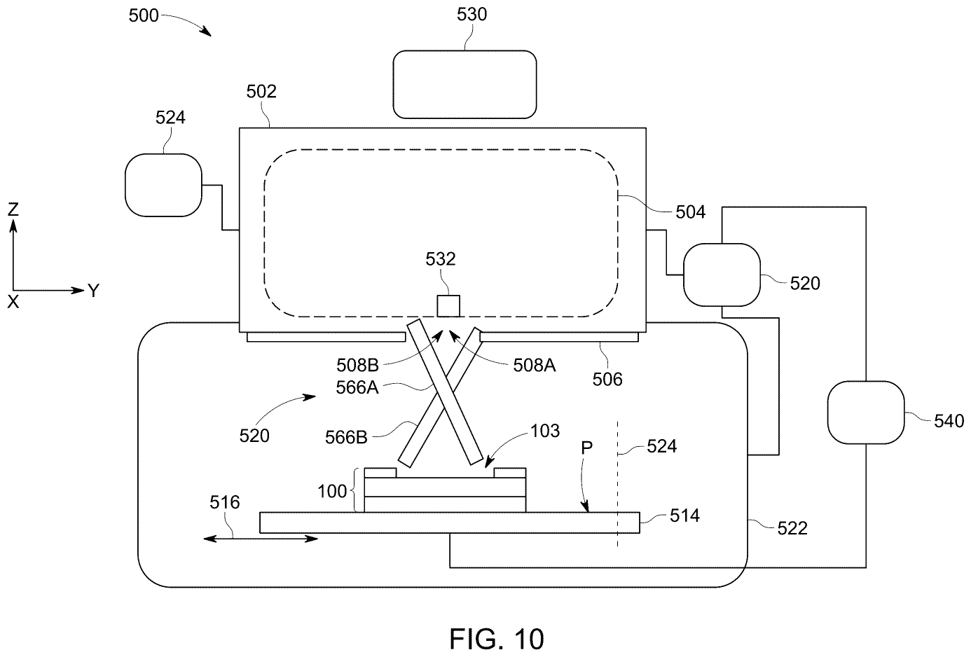

FIG. 10 depicts a side view of a processing apparatus 500 during ion beam processing of a substrate, in accordance with embodiments of the present disclosure. The processing apparatus 500 represents a tool for selectively etching one or more layers of a device, such as selectively removing portions of the insulator layer within trenches, as described herein. In some embodiments, the processing apparatus 500 may be located within etch chamber 314C of the tool 300 shown in FIG. 8.

The processing apparatus 500 may be a plasma-based processing system having a plasma chamber 502 for generating a plasma 504 therein by any convenient method as known in the art. A power supply 530, may, for example, be an RF power supply to generate the plasma 504. An extraction plate 506 may be provided as shown, having an extraction aperture 508, where a selective etching may be performed to selectively remove sidewall layers. A substrate, such as a substrate having the aforementioned structure(s) of devices 100 and/or 200 described above, is disposed in the process chamber 522.

A controller 540 may be provided to send control signals to the bias supply 520 and to a substrate stage 514. In one example, the view of FIG. 10 may represent a variant of the selective etching operation shown in FIG. 2, for example. During a directional etching operation, a plasma, such as a reactive plasma is formed using a reactive chemistry in the plasma chamber 502, and one or more angled ion beams 566A, 566B are extracted as a pair of ion beams, as shown. Although non-limiting, the processing apparatus 500 may include a beam blocker 532 disposed adjacent the extraction aperture 508. The beam blocker 532 is sized and positioned to define a first aperture 508A and a second aperture 508B, where the first aperture 508A forms the first angled ion beam 566A, and the second aperture 508B forms the second angled ion beam 566B. The two angled ion beams may define angles of incidence with respect to a perpendicular, equal in magnitude, opposite in direction. In one embodiment, the first angled ion beam 566A and the second angled ion beam 566B may represent an angled reactive ion beam. The beam blocker offset along the Z-axis with respect to extraction plate 506 may help define the angle of the angled ion beams.

In particular, as shown in FIG. 10, and with reference to the device 100 shown in FIG. 2, the angled ion beams 566A-566B, each forming a non-zero angle of incidence with respect to the Z-axis (normal to the substrate plane), may strike the device 100. As such, the first angled ion beam 566A and the second angled ion beam 566B may selectively etch the insulator layer to remove a section of the insulator layer from the upper portion of just one sidewall of the trench 103. In the embodiment shown in FIG. 2, only a single angled ion beam (e.g., 566B) may be extracted and delivered to the trench 103.

The angled ion beams 566A, 566B may be extracted when a voltage difference is applied using a bias voltage source, shown as bias supply 520, between the plasma chamber 502 and device 100, as in known systems. The bias supply 520 may be coupled to the process chamber 522, for example, where the process chamber 522 and device 100 are held at the same potential. In various embodiments, the angled ion beams 566A, 566B may be extracted as a continuous beam or as a pulsed ion beam as in known systems. For example, the bias supply 520 may be configured to supply a voltage difference between plasma chamber 502 and process chamber 522, as a pulsed DC voltage, where the voltage, pulse frequency, and duty cycle of the pulsed voltage may be independently adjusted from one another. When configured in the shape of a ribbon beam, these angled ion beams may expose an entirety of the device 100 to reactive ion etching of the trenches distributed in devices across the substrate, by scanning the substrate stage 514 along the scan direction 516, as shown. In some examples, the substrate stage 514 may be heated or cooled to a desired temperature. In other examples, the ion beams 566A, 566B may each be a spot beam.

In various embodiments, the value of the non-zero angle of incidence may vary from 5 degrees to 85 degrees, while in some embodiments the value may range between 15 degrees and 60 degrees. The embodiments are not limited in this context. The angled ion beams 566A, 566B may be composed of any convenient gas mixture, including inert gas, reactive gas, and may be provided in conjunction with other gaseous species in some embodiments. Gas may be provided from a gas source 524, where the gas source 524 may be a gas manifold coupled to provide a plurality of different gases to the plasma chamber 502. In particular embodiments, the angled ion beams 566A, 566B and other reactive species may be provided as a predetermined etch recipe to the device 100 so as to perform a directed reactive ion etching of targeted sidewalls of patterning layers on device 100. The etch recipe may be selective with respect to the material of the device 100, so as to remove material of the insulator layer, while not etching the sidewalls defining the trench, or etching the vertical structures sidewalls to a lesser extent.

In some embodiments, the processing apparatus 500 may be a GCIB or GCB tool operable to irradiate a gas ion beam to the upper portions of the trench oxide within the trenches, as described herein. For example, the processing apparatus 500 may form a gas cluster ion beam from a pressurized gas containing a deposition-etch gas, and expose the trench oxide to the GCIB to remove at least a portion thereof.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

In addition to the techniques disclosed above, as used herein, “depositing” and/or “deposited” may include any now known or later developed techniques appropriate for the material to be deposited including yet not limited to, for example: semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), chemical oxidation, molecular beam epitaxy (MBE), plating, and evaporation.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing an insulator layer along a first sidewall and a second sidewall of each trench of a plurality of trenches, wherein the plurality of trenches are formed in a base layer of a semiconductor device;
removing, in response to an ion treatment, the insulator layer from the first sidewall without substantially removing the insulator layer from the second sidewall, wherein the ion treatment comprises ions delivered to the first sidewall at a non-zero angle relative to a perpendicular extending from a plane defined by an upper surface of the base layer; and
forming a second insulator layer along the first sidewall, wherein a first thickness of the insulator layer is greater than a second thickness of the second insulator layer.

2. The method of claim 1, further comprising forming a gate material within the plurality of trenches following formation of the second insulator layer.

3. The method of claim 2, further comprising forming a p-body and an n+ contact region adjacent the second insulator layer.

4. The method of claim 1, wherein the ion treatment is an etch process.

5. The method of claim 1, wherein the ion treatment is an ion implant, and wherein the ion implant modifies an etch rate of the insulator layer along the first sidewall.

6. The method of claim 5, further comprising performing an etch process following the ion implant.

7. The method of claim 6, wherein the etch process is a wet etch, and wherein the wet etch removes the insulator layer from an upper portion of the first sidewall without substantially removing the insulator layer form a lower portion of the first sidewall.

8. The method of claim 1, wherein the ion treatment comprises delivering ions to an upper portion of the first sidewall without delivering ions to a lower portion of the first sidewall.

9. The method of claim 1, wherein the second insulator layer is an oxide grown along an upper portion of the first sidewall.

10. A method forming an asymmetrical trench insulator layer, the method comprising:
providing an insulator layer along a first sidewall and a second sidewall of each trench of a plurality of trenches, wherein the plurality of trenches are formed in a base layer of a transistor;
removing, in response to an ion treatment, the insulator layer from an upper portion of the first sidewall without substantially removing the insulator layer from the second sidewall, wherein the ion treatment comprises ions delivered to the first sidewall at a non-zero angle relative to a perpendicular extending from a plane defined by an upper surface of the base layer; and
forming a second insulator layer along the first sidewall, wherein a first thickness of the insulator layer is greater than a second thickness of the second insulator layer.

11. The method of claim 10, further comprising:
forming a gate material within the plurality of trenches following formation of the second insulator layer; and
forming a p-body and an n+ contact region adjacent the gate material.

12. The method of claim 10, wherein the ion treatment is one of: a first etch process, and an ion implant, wherein the ion implant modifies an etch rate of the insulator layer along the upper portion of the first sidewall.

13. The method of claim 12, further comprising performing a second etch process following the ion implant.

14. The method of claim 13, wherein the second etch process is a wet etch, and wherein the wet etch removes the insulator layer from the upper portion of the first sidewall without removing the insulator layer form a lower portion of the first sidewall.

15. The method of claim 10, wherein the ion treatment comprises delivering ions to the upper portion of the first sidewall without delivering ions to a lower portion of the first sidewall.

16. The method of claim 10, wherein the second insulator layer is an oxide grown along the upper portion of the first sidewall.

17. A method forming an asymmetrical trench oxide layer, the method comprising:
providing a trench oxide layer along a first sidewall and a second sidewall of each trench of a plurality of trenches, wherein the plurality of trenches are formed in a base layer of a transistor;
removing, in response to an ion treatment, the trench oxide layer from an upper portion of the first sidewall without substantially removing the trench oxide layer from a lower portion of the first sidewall, wherein the ion treatment comprises ions delivered to the first sidewall at a non-zero angle relative to a perpendicular extending from a plane defined by an upper surface of the base layer; and
forming a second trench oxide layer along the first sidewall, wherein a first thickness of the trench oxide layer is greater than a second thickness of the second trench oxide layer.

18. The method of claim 17, further comprising:
forming a gate material within the plurality of trenches following formation of the second insulator layer; and
forming a p-body and an n+ contact region adjacent the gate material.

19. The method of claim 17, wherein the ion treatment is one of: a first etch process, and an ion implant, wherein the ion implant modifies an etch rate of the trench oxide layer along the upper portion of the first sidewall.

20. The method of claim 19, further comprising performing a second etch process following the ion implant, wherein the second etch process is a wet etch, and wherein the wet etch removes the trench oxide layer from the upper portion of the first sidewall without substantially removing the trench oxide layer form the lower portion of the first sidewall.
